(19) United States
(12) Patent Application Publication
(10) Pub. No.: US 2017/0156226 A1
(43) Pub. Date: Jun. 1, 2017

(54) POWER CONVERTER

(71) Applicant: FUJI ELECTRIC CO., LTD., Kawasaki-shi (JP)

(72) Inventor: Tomo KUROZAKI, Kobe-shi (JP)

(21) Appl. No.: 15/276,066

(22) Filed: Sep. 26, 2016

(30) Foreign Application Priority Data
Nov. 30, 2015 (JP) 2015-233445

(51) Int. Cl. H05K 5/02; H05K 5/03

(52) U.S. Cl. CPC H05K 5/0217; H05K 5/03

(57) ABSTRACT

A power converter includes a mounting shelf arranged above or on a bottom plate. On the mounting shelf, a unit including wheels on a bottom surface is mounted removably in a front-rear direction. The power converter further includes a housing. The housing includes a pair of attachment portions respectively arranged on front edges of a pair of left and right side plates. The power converter further includes a protective cover. The protective cover is configured to secure the unit removably mounted on the mounting shelf between the pair of the attachment portions, and to protect the unit from the outside. From a state where the protective cover is removed, insertion nails arranged at a first edge of the protective cover are respectively inserted into insertion openings arranged at the mounting shelf to support the first edge of the protective cover.

### CROSS REFERENCE TO RELATED APPLICATIONS AND INCORPORATION BY REFERENCE

This application claims benefit of priority under 35 USC 119 based on Japanese Patent Application No. 2015-233445 filed on Nov. 30, 2015, the entire contents of which are incorporated by reference herein.

### BACKGROUND OF THE INVENTION

### Field of the Invention

The present invention relates to a power converter in which a unit is removably housed in a housing, the unit being configured to accommodate an electric circuit in a square-shaped chassis.

As a known power converter of this type, for example, the power converter disclosed by JP 2002-271921 A is known. The power converter disclosed by JP 2002-271921 A includes a housing including a horizontal member, a unit in which an electric circuit is accommodated in a square-shaped chassis and which can be drawn on the horizontal member, and a lock mechanism to prevent the unit from being drawn horizontally. The horizontal member includes a tray having a flat plate shape, and two spacer rails. Each of the spacer rails is made of a flat plate having a predetermined thickness, and the spacer rails are arranged at both upper ends of the tray to be horizontal in the front-rear direction of the tray. Additionally, plural ball casters are attached at the bottom of the unit, and are to be mounted on the spacer rails. The lock mechanism is configured with a protrusion, which is bent downward from the bottom plate forming the bottom of the unit.

In drawing out the unit, a lifter of elevation type is arranged at a predetermined position, and the nail of the arm of the lifter is mounted at a position on the tray in contact with the spacer rail. The nail of the arm and the spacer rail are same in thickness. When the unit is drawn on the nail side of the arm, the ball casters move onto the nail, and the unit is carried on the arm of the lifter. Thus, by use of the lifter, the unit is removable from the housing of the power converter.

### SUMMARY OF THE INVENTION

In the known power converter disclosed in JP 2002-271921 A, however, the inventors of the present invention have found the following drawbacks.

To draw out the unit from the housing safely, the lock mechanism is provided at the bottom plate forming the bottom of the unit. This configuration complicates the structure of drawing the unit from the housing, and may increase the manufacturing cost.

Besides, the unit cannot be taken out from the housing unless the lifter is provided separately. Hence, the whole apparatus to remove the unit from the housing is a large-sized one.

Therefore, the present invention has been made to address the above-described drawbacks, and an object of the present invention is to provide a power converter. A unit is removable safely from a housing of the power converter by using a simple structure without the provision of a lifter, and the manufacturing cost of the power converter is low.

According to one aspect of the present invention, there is provided a power converter including: a housing including a bottom plate, a top plate, a pair of left and right side plates, a rear plate, a mounting shelf arranged above or on the bottom plate and configured to mount a unit movably in a front-rear direction, the unit including a square-shaped chassis accommodating an electric circuit and wheels on a bottom surface of the chassis, and a pair of attachment portions respectively arranged on front edges of the pair of left and right side plates; a protective cover having a rectangular plate shape, and configured to secure the unit mounted on the mounting shelf to house the unit removably between the pair of attachment portions and protect the unit from the outside; an insertion opening arranged near a front edge of the mounting shelf; and an insertion nail arranged at a first edge of the protective cover to be insertable into the insertion opening. With the protective cover being removed, the insertion nail is inserted into the insertion opening to support the first edge side of the protective cover. With the insertion nail being inserted into the insertion opening, a second edge of the protective cover that is provided on an opposite side of the first edge of the protective cover is supported to make a slanted state where the protective cover is slanted downward from the first edge to the second edge, and the unit is movable on a main surface of the protective cover.

### BRIEF DESCRIPTION OF THE DRAWINGS

FIG. 1A is a left side view of a unit to be housed in a housing of a power converter in one embodiment of the present invention;

FIG. 1B is a front view of the unit to be housed in the housing of the power converter in one embodiment of the present invention;

FIG. 2 is a perspective view of the power converter, in a state where a protective cover is removed from the housing of the power converter in one embodiment of the present invention;

FIG. 3 is a perspective view of the power converter, in a state where the protective cover is attached at the housing of the power converter from the state illustrated in FIG. 2, in one embodiment of the present invention;

FIG. 4 is a perspective view of the power converter, in a state where the protective cover is removed from the state illustrated in FIG. 3, in one embodiment of the present invention;

FIG. 5 is a perspective view of a slanted state where the protective cover is slanted downward from a lower edge where the insertion nails of the protective cover are arranged to an upper edge which is arranged on the opposite side of the lower edge, and the upper edge is supported on the ground, on the floor, or the like, by inserting insertion nails of the protective cover respectively into insertion openings in the housing of the power converter from the state illustrated in FIG. 4; and

FIG. 6 is a perspective view of a state where the unit abuts a stopper, after the unit moves over a main surface of the protective cover from the state illustrated in FIG. 5.

### DETAILED DESCRIPTION

Embodiments of the present invention will be described with reference to the attached drawings.

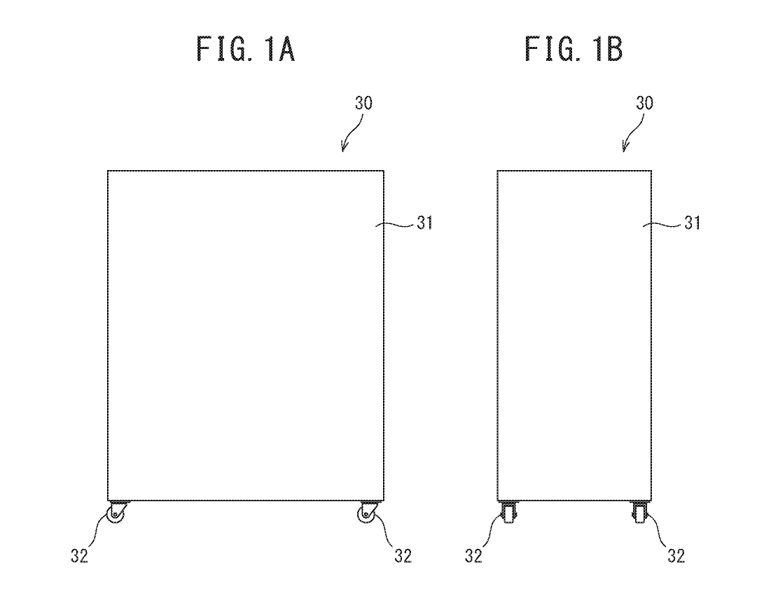

FIG. 1A and FIG. 1B illustrate a unit to be housed in a housing of a power converter in one embodiment of the present invention. A unit 30 includes four wheels 32 at four corners of the bottom face of a square-shaped chassis 31. In the square-shaped chassis 31, an electric circuit such as a rectifier, a smoothing circuit, or an inverter circuit is accommodated.

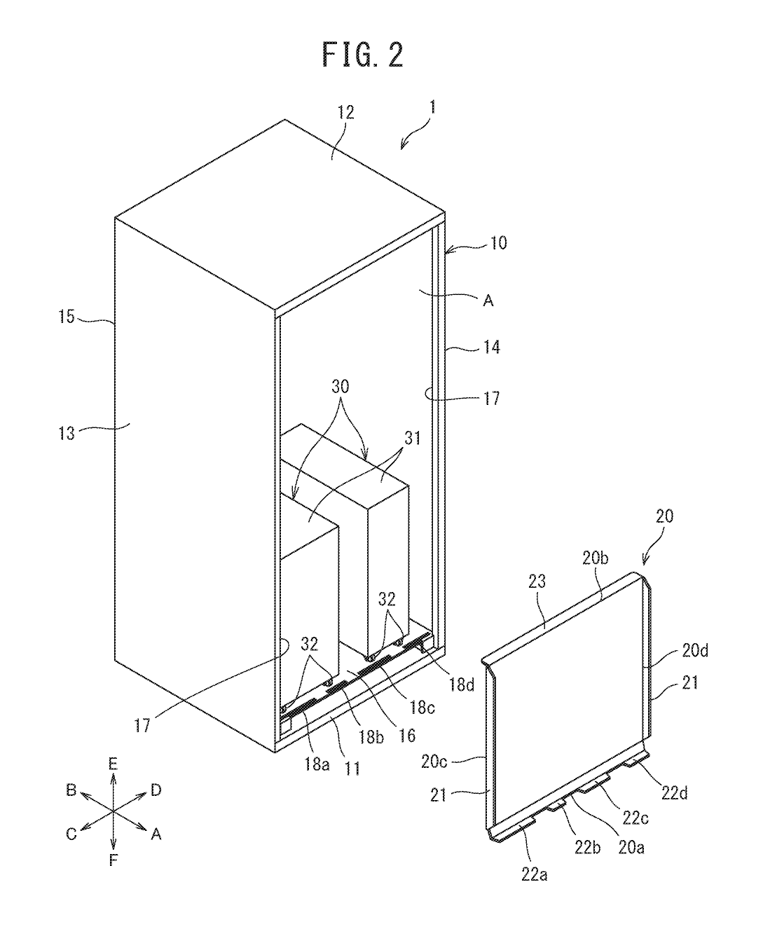

As illustrated in FIG. 2, a power converter 1 includes a housing 10 and a protective cover 20.

As illustrated in FIG. 2, the housing 10 is configured to have a substantially rectangular parallelepiped shape extending as indicated by arrows AB, CD, and EF. The arrow AB indicates a front-rear direction, the arrow CD indicates a left-right direction, which is perpendicular to the front-rear direction, and the arrow EF indicates an up-down direction, which is perpendicular to the front-rear direction and the left-right direction. Herein, the arrow A indicates a frontward direction, the arrow B indicates a rearward direction, the arrow C indicates a leftward direction, the arrow D indicates a rightward direction, the arrow E indicates an upward direction, and the arrow F indicates a downward direction. Hereinafter, the directions will be described based on the above directions herein.

The housing 10 includes a bottom plate 11, a top plate 12, a pair of left and right side plates 13 and 14, and a rear plate 15, so that a unit-housing space A is formed to house plural units 30 in the inside of a unit-housing space A with the front side being opened.

Above or on the bottom plate 11 of the housing 10, in the unit-housing space A, a mounting shelf 16 configured to mount the plural units 30 movably in the front-rear direction is arranged. The mounting shelf 16 is disposed above or on the bottom plate 11 such that the top surface of the mounting shelf 16, on which wheels 32 of each unit 30 are mounted, is higher than the top surface of the bottom plate 11. The mounting shelf 16 is made of a flat plate having a rectangular parallelepiped shape that covers the bottom plate 11 in the housing 10, and is disposed to extend in the horizontal direction parallel to the horizontal direction that the bottom plate 11 extends.

A pair of attachment portions 17 are arranged at front edges of the pair of left and right side plates 13 and 14 of the housing 10. Between the pair of attachment portions 17, the protective cover 20 is removably attached, as will be described later.

Additionally, plural (four is a non-limiting example) insertion openings 18a, 18b, 18c, and 18d are arranged near the front edge of the mounting shelf 16 of the housing 10. From the state where the protective cover 20 is removed, insertion nails 22a, 22b, 22c, and 22d of the protective cover 20 are respectively inserted into the insertion openings 18a, 18b, 18c, and 18d, as will be described later.

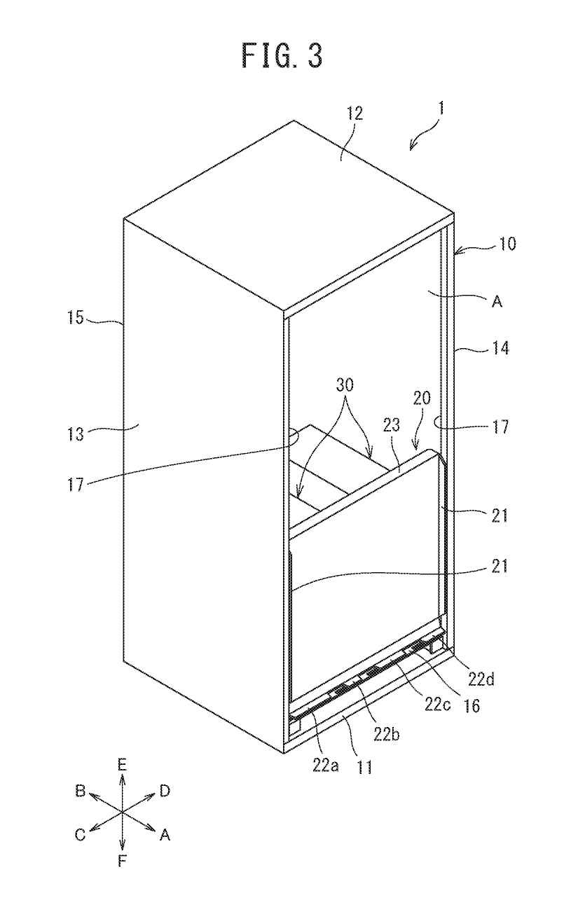

Next, as illustrated in FIG. 2, the protective cover 20 is a metal member that is formed to have a rectangular flat plate shape, and is formed by punching and bending a metal plate. A pair of attachment pieces 21 are respectively provided at a left edge 20c and a right edge 20d of the protective cover 20. Each attachment piece 21 is formed to bend frontward from the left edge 20c or the right edge 20d of the protective cover 20, and extends from the upper edge of the protective cover 20 to reach near the lower edge. As illustrated in FIG. 3, the protective cover 20 is attached between the pair of attachment portions 17 from the front side of the housing 10. In the attachment, each attachment piece 21 is brought into contact with the inside of the attachment portion 17 and is pressed into the attachment portion 17 to have a function of elastically supporting the protective cover 20. The protective cover 20 is removable from the housing 10 by pressing frontward from the rear side. The protective cover 20 has an area larger than an area that convers the front surfaces of the plural units 30. As illustrated in FIG. 3, when the protective cover 20 is attached to the housing 10, the protective cover 20 presses the plural units 30 from the front side, and secures the plural units 30 between the protective cover 20 and the rear plate 15. Further, in this situation, the protective cover 20 protects the plural units 30 and conductive parts, not illustrated, from the outside of the housing 10.

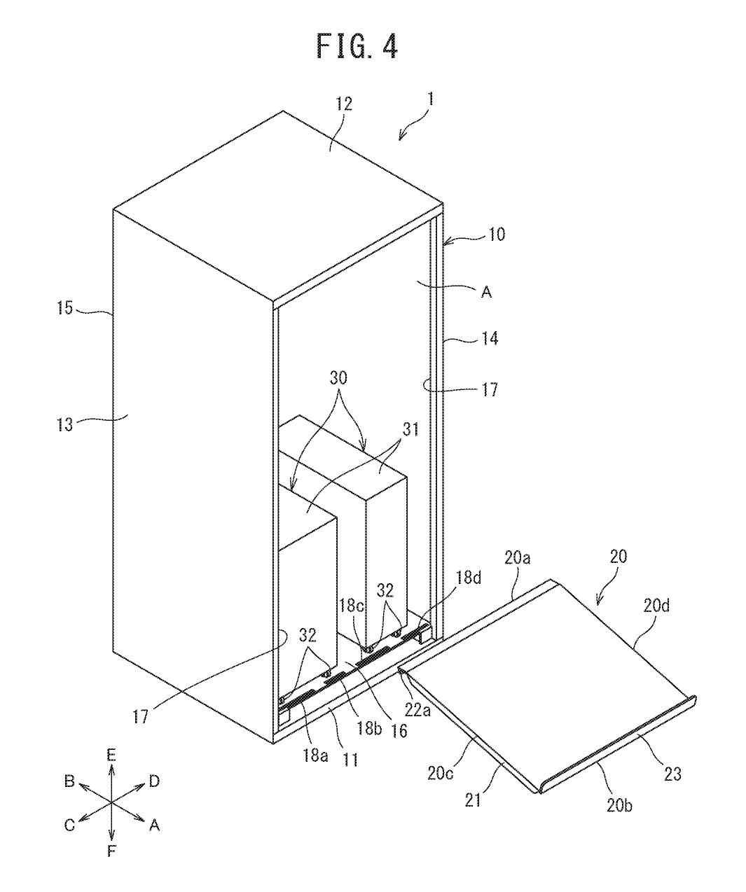

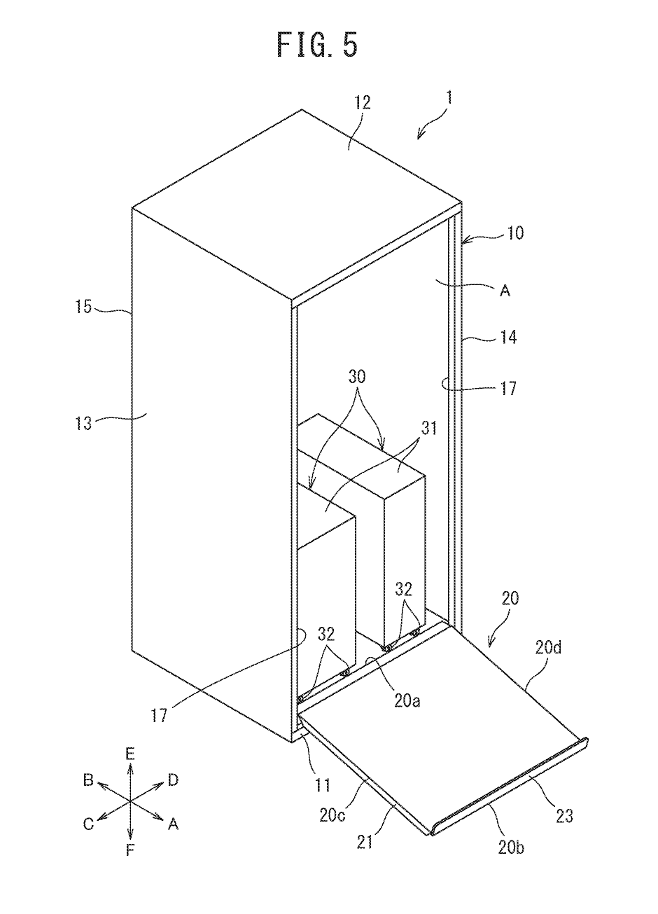

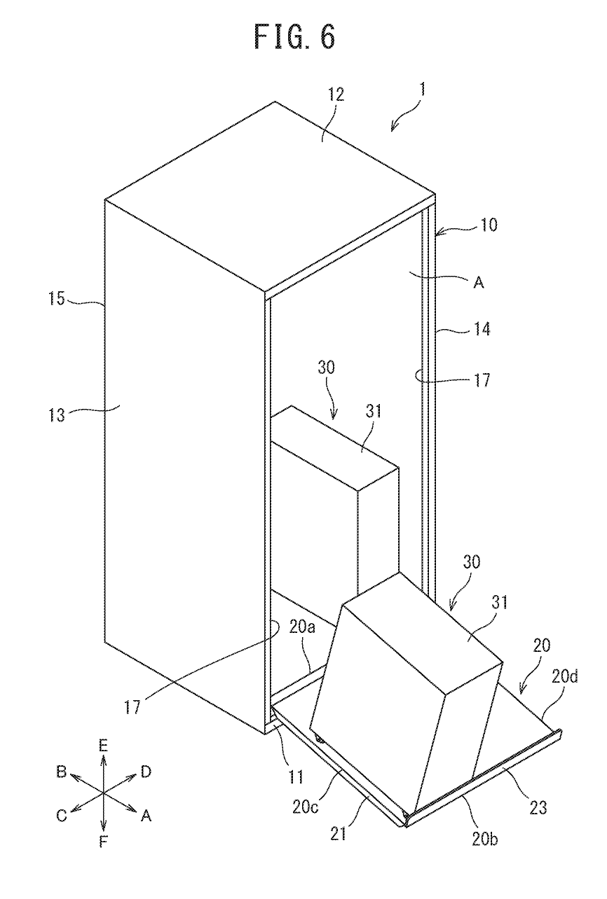

At a lower edge 20a of the protective cover 20, plural (four is a non-limiting example) insertion nails 22a, 22b, 22c, and 22d are provided to be respectively insertable into the plural insertion openings 18a, 18b, 18c, and 18d arranged at the mounting shelf 16. Each of the insertion nails 22a, 22b, 22c, and 22d is formed to bend frontward from the lower edge 20a of the protective cover 20. As illustrated in FIG. 3, the insertion nails 22a, 22b, 22c, and 22d are located on the top surface near the front edge of the mounting shelf 16, when the protective cover 20 is attached to the housing 10. The insertion nails 22a, 22b, 22c, and 22d are respectively inserted into the insertion openings 18a, 18b, 18c, and 18d with the protective cover 20 being removed from the housing 10 (i.e., the state illustrated in FIG. 4). The lower edge 20a of the protective cover 20 is supported by the mounting shelf 16, accordingly (see FIG. 5). On the other hand, an upper edge 20b of the protective cover 20 can be supported on the ground, on the floor, or the like, with the upper edge 20b being arranged on the opposite side of the lower edge 20a where the insertion nails 22a, 22b, 22c, and 22d are arranged. Hence, the protective cover 20 is made into a slanted state where the protective cover 20 is slanted downward from the lower edge 20a to the upper edge 20b. As illustrated in FIG. 6, each unit 30 mounted on the mounting shelf 16 is movable on the main surface of the protective cover 20 via the wheels 32.

Further, as illustrated in FIG. 6, the upper edge 20b of the protective cover 20 includes a stopper 23 configured to stop the movement of the protective cover 20. The stopper 23 is formed to bend rearward from the upper edge 20b of the protective cover 20, and extends from the vicinity of the left edge to the vicinity of the right edge of the protective cover 20.

A method of housing each unit 30 in the housing 10 of the power converter 1 and a method of removing each unit 30 from the housing 10 will be described with reference to FIG. 2 to FIG. 6.

Firstly, as illustrated in FIG. 2, in order to house each unit 30 in the housing 10 of the power converter 1, the protective cover 20 is removed from the housing 10. In this state, each unit 30 is mounted on the mounting shelf 16 with the wheels 32 facing down.

Next, as illustrated in FIG. 3, the protective cover 20 is attached between the pair of attachment portions 17 from the front side of the housing 10. In the attachment, each of the attachment pieces 21 of the protective cover 20 is brought into contact with the inside of the attachment portion 17 and is pressed into the attachment portion 17, so that the protective cover 20 is elastically supported. The insertion nails 22a, 22b, 22c, and 22d of the protective cover 20 are located on the top surface of the mounting shelf 16 near the front edge. Thus, the protective cover 20 presses each of the units 30 from the front side, and secures the plural units 30 between the protective cover 20 and the rear plate 15 of the housing 10. In this situation, the protective cover 30 protects the plural units 30 and the conductive parts, not illustrated, from the outside of the housing 10.

In order to remove each unit 30 from the housing 10, firstly, by pressing frontward the protective cover 20 from the rear side, the protective cover 20 is removed from the housing, as illustrated in FIG. 4. With the protective cover 20 being removed from the housing 10 (i.e., the state illustrated in FIG. 4), the insertion nails 22a, 22b, 22c, and 22d of the protective cover 20 are respectively inserted into the insertion openings 18a, 18b, 18c, and 18d, as illustrated in FIG. 5. The lower edge 20a of the protective cover 20 is supported by the mounting shelf 16, accordingly. On the other hand, the upper edge 20b of the protective cover 20 is supported on the ground, on the floor, or the like, with the upper edge 20b being arranged on the opposite side of the lower edge 20a where the insertion nails 22a, 22b, 22c, and 22d are arranged. Hence, the protective cover 20 is made into a slanted state where the protective cover 20 is slanted downward from the lower edge 20a to the upper edge 20b.

This configuration enables each unit 30 mounted on the mounting shelf 16 to move over the main surface of the protective cover 20, as illustrated in FIG. 6. Therefore, each unit 30 is made to move obliquely downward over the main surface of the protective cover 30 via the wheels 32, and then each unit 30 is removed.

As described above, according to the power converter 1 in one embodiment of the present invention, the insertion openings 18a, 18b, 18c, and 18d are arranged near the front edge of the mounting shelf 16 of the housing 10, and in addition, the insertion nails 22a, 22b, 22c, and 22d to be respectively insertable into the insertion openings 18a, 18b, 18c, and 18d are arranged at the lower edge (i.e., a first edge) 20a of the protective cover 20. With the protective cover 20 being removed, the insertion nails 22a, 22b, 22c, and 22d are respectively inserted into the insertion openings 18a, 18b, 18c, and 18d, and the lower edge 20a of the protective cover 20 is supported. Additionally, the upper edge 20b (i.e., a second edge) of the protective cover 20 is supported on the ground, on the floor, or the like, with the upper edge 20b being arranged on the opposite side of the lower edge 20a where the insertion nails 22a, 22b, 22c, and 22d are arranged. The protective cover 20 is made into a slanted state of slanting downward from the lower edge 20a to the upper edge 20b. Then, each unit 30 becomes movable over the main surface of the protective cover 20. Such a simple structure makes each of the units 30 removable from the housing 10 safely, without the provision of a lifter.

The protective cover 20 is configured to secure each of the unit, and to protect the units 30 from the outside. The protective cover 20 is also configured to be a member of removing each of the units 30. The power converter is achieved with a fewer number of parts and a lower manufacturing cost.

When each unit 30 moves obliquely downward over the main surface of the protective cover 20, each unit 30 abuts the stopper 23 arranged on the upper edge 20b of the protective cover 20, and then its movement is stopped. This configuration prevents each unit 30 from moving intensely or going outside from the protective cover 20, and makes each unit 30 removable more safely.

After each unit 30 is removed from the housing 10, the protective cover 20 can be attached to the housing 10.

Heretofore, embodiments of the present invention have been described. However, the present invention is not limited to them. Various changes and improvements are applicable. For example, the protective cover 20 is made of a metal member. However, any material that bears the load of the unit 30 can be used other than metal. The insertion nails 22a, 22b, 22c, and 22d are arranged at the lower edge 20a of the protective cover 20, but, may be arranged at the upper edge 20b of the protective cover 20.

### REFERENCE SIGNS LIST

1 power converter

10 housing

11 bottom plate

12 top plate

13, 14 side plates

15 rear plate

16 mounting shelf

17 attachment portion

18a, 18b, 18c, 18d insertion openings

20 protective cover

20a lower edge (first edge)

20b upper edge (second edge on the opposite side of the first edge)

22a, 22b, 22c, 22d insertion nails

23 stopper

30 unit

31 chassis

32a wheel

1. A power converter comprising:
a housing comprising: a bottom plate; a top plate; a pair of left and right side plates; a rear plate; a mounting shelf arranged above or on the bottom plate and configured to mount a unit movably in a front-rear direction, the unit comprising a square-shaped chassis accommodating an electric circuit and wheels on a bottom surface of the chassis; and a pair of attachment portions respectively arranged on front edges of the pair of left and right side plates;
a protective cover having a rectangular plate shape, and configured to secure the unit mounted on the mounting shelf to house the unit removably between the pair of attachment portions and protect the unit from the outside;
an insertion opening arranged near a front edge of the mounting shelf; and
an insertion nail arranged at a first edge of the protective cover to be insertable into the insertion opening,
wherein with the protective cover being removed, the insertion nail is inserted into the insertion opening to support the first edge side of the protective cover, and
wherein with the insertion nail being inserted into the insertion opening, a second edge of the protective cover that is provided on an opposite side of the first edge of the protective cover is supported to make a slanted state where the protective cover is slanted downward from the first edge to the second edge, and the unit is movable on a main surface of the protective cover.

2. The power converter further comprising a stopper arranged at the second edge of the protective cover to stop a movement of the protective cover.
